(19) United States
(12) Patent Application Publication
(10) Pub. No.: US 2025/0218727 A1
(43) Pub. Date: Jul. 3, 2025

(54) PLASMA GENERATION CIRCUIT AND SUBSTRATE PROCESSING DEVICE INCLUDING THE SAME

(71) Applicant: SAMSUNG ELECTRONICS CO., LTD., Suwon-si (KR)

(72) Inventors: Sungyong LIM, Suwon-si (KR); Kyungmin LEE, Suwon-si (KR); Hadong JIN, Suwon-si (KR); Kyungsun KIM, Suwon-si (KR); Namkyun KIM, Suwon-si (KR); Sungyeol KIM, Suwon-si (KR); Donghyeon NA, Suwon-si (KR)

(73) Assignee: SAMSUNG ELECTRONICS CO., LTD., Suwon-si (KR)

(21) Appl. No.: 18/910,685

(22) Filed: Oct. 9, 2024

(30) Foreign Application Priority Data
Jan. 2, 2024 (KR) 10-2024-0000497

(51) Int. Cl. H01J 37/32

(52) U.S. Cl. CPC H01J 37/32183; H01J 37/32155

(57) ABSTRACT

A plasma generation circuit includes a power generator including a first function output unit configured to generate a first harmonic signal and a second function output unit configured to generate a compensation signal; a load unit electrically connected to one side of the power generator and configured to transmit the first harmonic signal and the compensation signal to a sensor; and a controller connected to the power generator and the sensor, wherein the sensor is provided between the load unit and an electrode configured to generate plasma based on receiving the first harmonic signal and the compensation signal, the controller is configured to generate a control signal based on the first harmonic signal received from the sensor, and the second function output unit is configured to generate the compensation signal based on the control signal.

### CROSS-REFERENCE TO RELATED APPLICATION

This application is based on and claims priority under 35 U.S.C. § 119 to Korean Patent Application No. 10-2024-0000497, filed on Jan. 2, 2024, in the Korean Intellectual Property Office, the disclosure of which is incorporated by reference herein in its entirety.

### BACKGROUND

The present disclosure relates to a plasma generation circuit and a substrate processing device including the plasma generation circuit.

An example of a process of manufacturing semiconductor devices includes a plasma process including plasma-induced deposition, plasma etching, and plasma cleaning. Recently, with the miniaturization and high integration of semiconductor devices, the impact of subtle errors in the plasma process on the quality of semiconductor products has increased. Accordingly, various technologies for precisely simulating the plasma process have been proposed.

### SUMMARY

One or more embodiments provide a plasma generation circuit which may have improved reliability.

Further, one or more embodiments provide a substrate processing device including a plasma generation circuit which may have improved reliability.

According to an aspect of the disclosure, a plasma generation circuit includes: a power generator including a first function output unit configured to generate a first harmonic signal and a second function output unit configured to generate a compensation signal; a load unit electrically connected to one side of the power generator and configured to transmit the first harmonic signal and the compensation signal to a sensor; and a controller connected to the power generator and the sensor, wherein the sensor is provided between the load unit and an electrode configured to generate plasma based on receiving the first harmonic signal and the compensation signal, the controller is configured to generate a control signal based on the first harmonic signal received from the sensor, and the second function output unit is configured to generate the compensation signal based on the control signal.

According to an aspect of the disclosure, a plasma generation circuit for supplying power to a plasma chamber, includes: a power generator including a first function output unit configured to generate a first harmonic signal transmitted to the plasma chamber and a second function output unit configured to generate a compensation signal; a filter electrically connected to the power generator and configured to adjust the first harmonic signal and the compensation signal; a sensor provided on an electrode of the plasma chamber and configured to measure a voltage and a current of each of the first harmonic signal and the compensation signal; a load unit located between the power generator and the sensor and configured to transmit the first harmonic signal and the compensation signal generated by the power generator to the sensor; and a controller connected to the power generator, the filter, and the sensor, wherein the controller is configured to generate a control signal based on the first harmonic signal received from the sensor, the control signal is transmitted to the power generator and the filter, the compensation signal is generated based on the control signal generated by the second function output unit, the filter includes a plurality of compensation circuits, and impedances of the plurality of compensation circuits are adjusted by the control signal generated by the controller.

According to an aspect of the disclosure, a substrate processing device includes: a chamber constituting a space for plasma processing a substrate; a gas supply configured to supply plasma gas into the chamber; an electrode unit including an upper electrode and a lower electrode that are configured to cause a plasma generation reaction from the plasma gas; and a plasma generation circuit configured to transmit a first harmonic signal to the upper electrode and the lower electrode, wherein the plasma generation circuit includes: a power generator including a first function output unit configured to generate the first harmonic signal and a second function output unit configured to generate a compensation signal; a filter electrically connected to the power generator and configured to adjust the first harmonic signal and the compensation signal; a sensor located on the upper electrode or the lower electrode and configured to measure a voltage and a current of each of the first harmonic signal and the compensation signal; a load unit located between the power generator and the sensor and configured to transmit the first harmonic signal and the compensation signal generated by the power generator to the sensor; and a controller connected to the power generator, the filter, and the sensor, and configured to generate a control signal based on the first harmonic signal received from the sensor, wherein the second function output unit is configured to generate the compensation signal as a second harmonic signal based on the control signal, the filter includes a plurality of compensation circuits, at least one compensation circuit of the plurality of compensation circuits is connected to the upper electrode, and impedances of the plurality of compensation circuits are adjusted by the control signal generated by the controller.

### BRIEF DESCRIPTION OF THE DRAWINGS

Embodiments will be more clearly understood from the following detailed description taken in conjunction with the accompanying drawings, in which:

FIG. 1 is a circuit diagram of a plasma generation circuit according to an embodiment;

FIG. 2 is a circuit diagram showing in detail a second function output unit included in a power generator;

FIG. 3 is a set of circuit diagrams listing components of a compensation circuit, according to embodiments;

FIG. 4 is a conceptual diagram listing a modified example of a compensation signal;

FIGS. 5 to 9 are graphs showing a process of compensating for a deteriorated first harmonic signal;

FIG. 10 is a diagram for explaining a substrate processing device including a plasma generation circuit according to an embodiment;

FIG. 11 is a flowchart of a semiconductor device manufacturing method including plasma process simulation according to an embodiment; and

FIG. 12 is a block diagram showing a computing system according to an embodiment.

### DETAILED DESCRIPTION

The embodiments may be modified in various ways and may take various other forms, and certain embodiments will be illustrated in the drawings and described in detail herein. However, this is not intended to limit the embodiments to the certain forms disclosed herein. The embodiments described below are merely illustrative, and various modifications are possible from the embodiments.

The use of all examples or illustrative terms is simply for explaining the technical spirit in detail, and the scope is not limited by these examples or illustrative terms unless limited by the claims.

Unless otherwise described below, in this specification, a vertical direction is defined as a Z direction, and a first direction and a second direction may each be defined as vertical directions perpendicular to the Z direction. The first direction may be referred to as X and the second direction may be referred to as Y. A vertical level may refer to a height level in a vertical direction Z. A horizontal width may refer to a length in a horizontal direction X and/or Y, and a vertical length may refer to a length in the vertical direction Z.

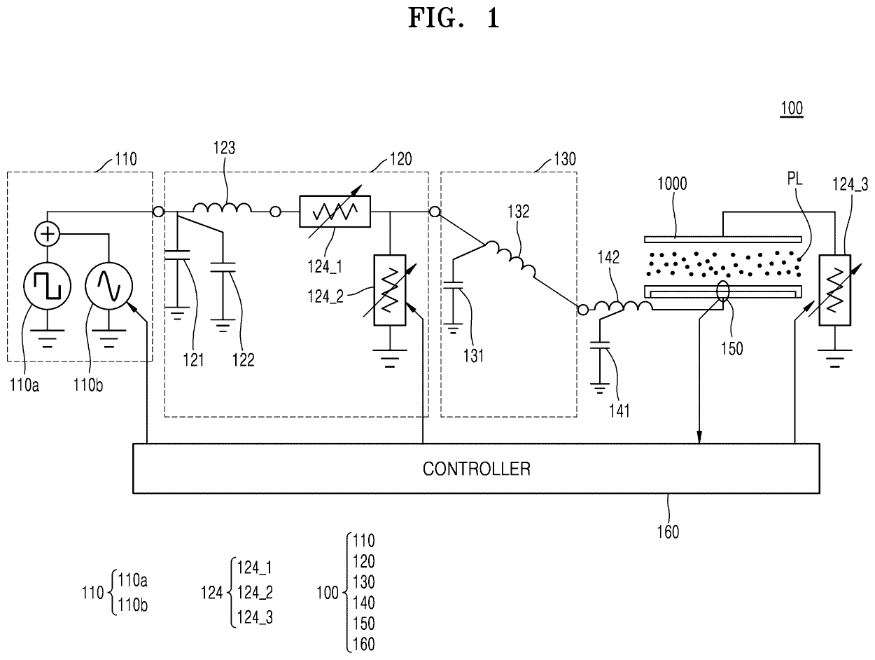

FIG. 1 is a circuit diagram of a plasma generation circuit according to an embodiment.

Referring to FIG. 1, a plasma generation circuit 100 may include a power generator 110. The power generator 110 may include a plurality of function output units and, according to an embodiment, may include a first function output unit 110a and a second function output unit 110b. The first function output unit 110a and the second function output unit 110b may each be configured to generate a harmonic signal.

The first function output unit 110a may generate a first harmonic signal, and the second function output unit 110b may generate a compensation signal. The first harmonic signal and the compensation signal that are respectively generated by the first function output unit 110a and the second function output unit 110b may be different from each other. The first harmonic signal generated by the first function output unit 110a may be in the form of a square wave. The compensation signal output by the second function output unit 110b may be a synthesized signal of a plurality of sine waves.

The first harmonic signal and the compensation signal that are respectively generated by the first function output unit 110a and the second function output unit 110b may be transmitted to a substrate processing device 1000 including a plasma chamber, and the first harmonic signal and the compensation signal may generate plasma PL in the substrate processing device 1000.

When the first harmonic signal generated by the first function output unit 110a reaches the plasma chamber, the first harmonic signal may be transformed or deteriorated differently from a shape output from the first function output unit 110a and output nonlinearly. The non-linearly output first harmonic signal may be compensated for by the harmonic signal generated from the second function output unit 110b. According to an embodiment, the second function output unit 110b may be configured to generate a compensation signal as a harmonic signal. The first function output unit 110a and the second function output unit 110b may each be implemented using oscillators, resistors, capacitors, phase lock loops, custom hardware and/or a CPU executing instructions stored in memory.

The plasma generation circuit 100 may include a filter 120 that adjusts the first harmonic signal and the compensation signal that are generated by the power generator 110, a sensor 150 that is located on an electrode of the substrate processing device 1000 and measures a voltage and a current of the first harmonic signal and the compensation signal, a load unit 130 located between the power generator 110 and the sensor 150 and transmitting the first harmonic signal and the compensation signal generated by the power generator 110 to the sensor 150, and a controller 160 connected to the power generator 110, the filter 120, and the sensor 150. The controller 160 may each be implemented using an analog to digital converter (ADC) custom hardware and/or a CPU executing instructions stored in memory.

The controller 160 may be configured to generate a control signal in response to the first harmonic signal received from the sensor 150.

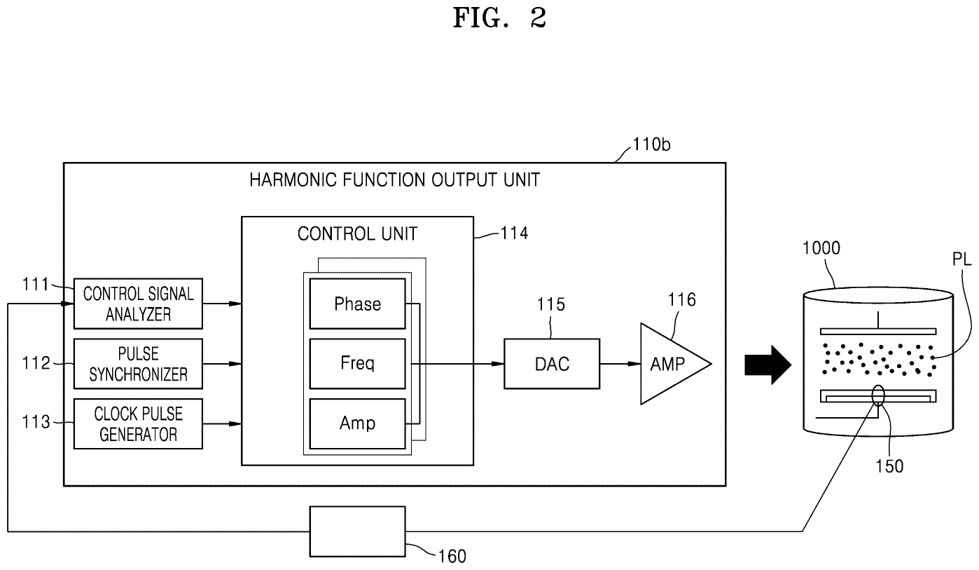

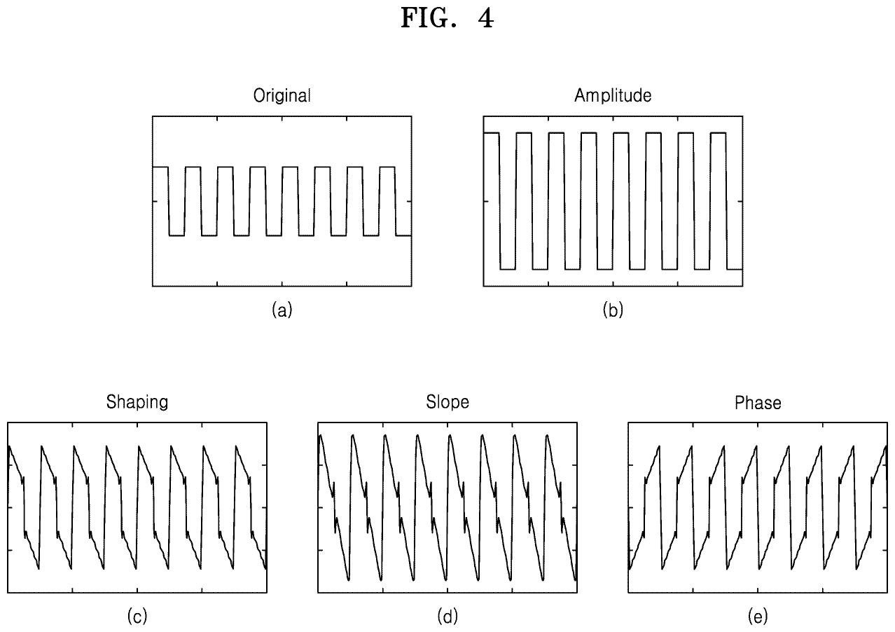

The second function output unit 110b is configured to generate a compensation signal as a harmonic signal in response to the control signal. The first harmonic signal generated from the first function output unit 110a may be compensated for by the compensation signal generated from the second function output unit in the substrate processing device 1000. The first harmonic signal generated from the first function output unit 110a and the compensation signal generated from the second function output unit 110b may overlap each other. That is, the second function output unit 110b may perform compensation when synthesizing a digital signal before signal amplification, based on input information about the nonlinearity of the first harmonic signal measured by the sensor 150. Amplification and digital signal synthesis of the second function output unit 110b will be described in detail in FIG. 2. A process of compensating for the first harmonic signal generated from the first function output unit 110a by the compensation signal generated from the second function output unit will be described in detail with reference to FIGS. 4 to 9.

The plasma generation circuit 100 may include a plurality of circuit components. A plurality of circuit components may be located on a path through which the first harmonic signal generated from the first function output unit 110a is transmitted to the substrate processing device 1000, and may cause deterioration of the first harmonic signal. According to an embodiment, the filter 120 may include a first filter capacitor 121, a second filter capacitor 122, and a filter inductor 123 as circuit components. According to an embodiment, the load unit 130 may include a load capacitor 131 and a load inductor 132 as circuit components. The plasma generation circuit 100 may include a chamber capacitor 141 and a chamber inductor 142 as circuit components in a path that reaches the substrate processing device 1000 after passing through the load unit 130. The first filter capacitor 121, the second filter capacitor 122, the filter inductor 123, the load capacitor 131, the load inductor 132, the chamber capacitor 141, and the chamber inductor 142 as the circuit components may cause distortion and deterioration of the first harmonic signal generated from the first function output unit 110a. In other words, the first harmonic signal generated from the first function output unit 110a may be distorted and deteriorated before reaching the substrate processing device 1000. The sensor 150 is not located in the middle of a path through which the first harmonic signal passes, but is located close to the substrate processing device 1000 adjacent to an electrode, according to an embodiment. The sensor 150 may be located adjacent to the electrode, and thus may detect most of the distortion and deterioration on the path, and the controller 160 may generate an accurate control signal for the first harmonic signal by transmitting the distortion and deterioration of the finally detected first harmonic signal to the controller 160. As distortion and deterioration occur in the first harmonic signal, nonlinearity of the first harmonic signal generated from the first function output unit 110a may occur. The number and location of the circuit components are merely an example and are not limited to the drawings.

The sensor 150 may measure the voltage and current of the first harmonic signal and the compensation signal. The controller 160 may receive the first harmonic signal and the compensation signal measured by the sensor 150, and the controller may generate a control signal based on the received first harmonic signal, and transmit the control signal to each of the second function output unit 110b and a compensation circuit 124.

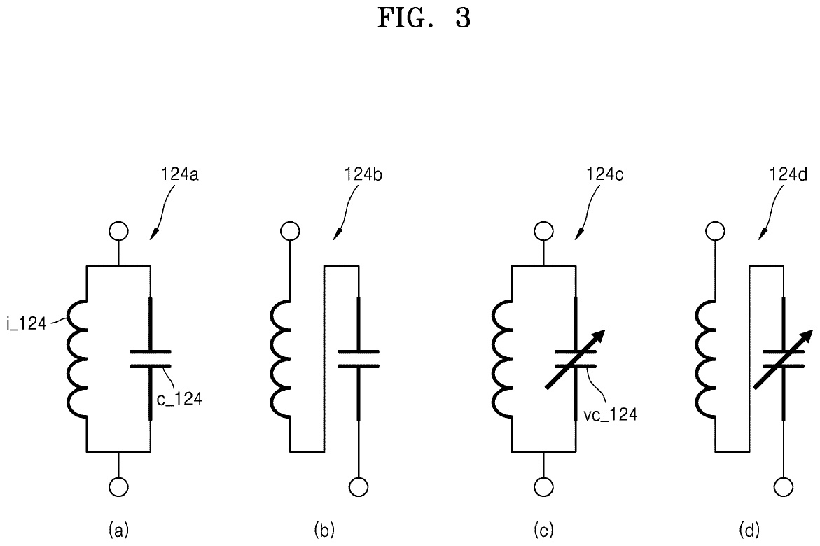

The filter 120 may include a plurality of compensation circuits 124. The plurality of compensation circuits 124 may include a first compensation circuit 124_1, a second compensation circuit 124_2, and a third compensation circuit 124_3. The substrate processing device 1000 may include an electrode, the electrode may include an upper electrode and a lower electrode, and at least one compensation circuit may be connected to the upper electrode from among the plurality of compensation circuits 124. According to an embodiment, the first compensation circuit 124_1 and the second compensation circuit 124_2 may be connected to the lower electrode, and the third compensation circuit 124_3 may be connected to the upper electrode. The arranged positions and number of the compensation circuits 124 shown in the drawing are not limited to the drawing. The plurality of compensation circuits 124 may each include a compensation inductor, a compensation capacitor, and a compensation variable capacitor, which will be described in detail in FIG. 3. The first compensation circuit 124_1 and the second compensation circuit 124_2 may be connected in series or parallel to each other, and a connection method of the first compensation circuit 124_1 and the second compensation circuit 124_2 is not limited to the drawing.

The plurality of compensation circuits 124 may each have an impedance, and the impedance may be adjusted by each component of the compensation circuit 124 and a control signal generated from the controller 160. The plurality of compensation circuits 124 may be configured to perform compensation feedback for distortion and deterioration of a harmonic function together with the compensation signal generated from the second function output unit 110b. The impedance of each of the plurality of compensation circuits 124 may be configured to match respective frequencies of the first harmonic signal and the compensation signal generated from the first function output unit 110a.

FIG. 2 is a circuit diagram showing in detail a second function output unit included in a power generator.

Referring to FIG. 2 together with FIG. 1, the second function output unit 110b may include a control signal analyzer 111 that analyzes a control signal received from the controller 160, a pulse synchronizer 112 configured to generate the compensation signal having the same frequency as the first harmonic signal generated by the first function output unit 110a, and a clock pulse generator 113 configured to generate the compensation signal. The second function output unit 110b may include a control unit 114 configured to control a phase, a frequency, and an amplitude of the compensation signal. The second function output unit 110b may further include a digital analog converter (DAC) 115 and an amplifier (AMP) 116. The DAC 115 may be configured to change the compensation signal, which is a digital signal, into an analog signal, and the AMP 116 may amplify an intensity, such as amplitude, of the changed analog signal. The second function output unit 110b may form the compensation signal based on the control signal received from the controller 160, and in detail, before amplifying a signal by the AMP 116, the second function output unit 110b may adjust a waveform by the control unit 114 and form a compensation signal when the DAC 115 synthesizes a digital signal. The control unit 114 be implemented using oscillators, resistors, capacitors, phase lock loops, custom hardware and/or a CPU executing instructions stored in memory.

The compensation signal refers to a signal of a function having an opposite sign to the difference between the observed signal and the first harmonic signal, as illustrated in FIG. 4A, to generate the first harmonic signal. Therefore, the control unit 114 calculates the difference between the observed signal and the first harmonic signal and computes the signal of a function having the opposite sign to the function with this difference. The control unit 114 transmits the calculated result to the DAC 115. In the process of calculating the difference between the observed signal and the first harmonic signal, phase, frequency, and amplitude may be computed. In this process, the controller 160 can calculate the phase, frequency, and amplitude of the observed signal.

The compensation signal generated by the second function output unit 110b may ultimately reach the substrate processing device 1000, and may be synthesized with the first harmonic signal generated by the first function output unit 110a in the substrate processing device 1000 to form the plasma PL. A frequency of the compensation signal generated by the second function output unit 110b may have the same frequency as a signal measured by the sensor 150.

FIG. 3 is a set of circuit diagrams listing components of a compensation circuit, according to embodiments.

Referring to FIG. 3 together with FIGS. 1 and 2, the compensation circuit 124 may include a compensation capacitor c_124, a compensation variable capacitor vc_124, and a compensation inductor i_124. The compensation inductor i_124 may be connected in series or parallel to one of the compensation capacitor c_124 and the compensation variable capacitor vc_124.

FIG. 3A illustrates a compensation circuit 124a. The compensation circuit 124a may include the compensation inductor i_124 and the compensation capacitor c_124. The compensation inductor i_124 and the compensation capacitor c_124 may be connected in parallel to each other. The inductance of the compensation inductor i_124 and the capacitance of the compensation capacitor c_124 may be configured differently depending on the properties of a substrate to be plasma processed, or may be configured differently for impedance matching based on the control signal transmitted from the controller 160.

FIG. 3B illustrates a compensation circuit 124b. The compensation circuit 124b may include the compensation inductor i_124 and the compensation capacitor c_124. The compensation inductor i_124 and the compensation capacitor c_124 may be connected in series to each other. The inductance of the compensation inductor i_124 and the capacitance of the compensation capacitor c_124 may be configured differently depending on the properties of a substrate to be plasma processed, or may be configured differently for impedance matching based on the control signal transmitted from the controller 160.

FIG. 3C illustrates a compensation circuit 124c. The compensation circuit 124c may include the compensation inductor i_124 and the compensation variable capacitor vc_124. The compensation inductor i_124 and the compensation variable capacitor vc_124 may be connected in parallel to each other. The inductance of the compensation inductor i_124 and the capacitance of the compensation variable capacitor vc_124 may be configured differently or varied depending on the properties of a substrate to be plasma processed, or may be configured differently or varied for impedance matching based on the control signal transmitted from the controller 160.

FIG. 3D illustrates a compensation circuit 124d. The compensation circuit 124d may include the compensation inductor i_124 and the compensation variable capacitor vc_124. The compensation inductor i_124 and the compensation variable capacitor vc_124 may be connected in series to each other. The inductance of the compensation inductor i_124 and the capacitance of the compensation variable capacitor vc_124 may be configured differently or varied depending on the properties of a substrate to be plasma processed, or may be configured differently or varied for impedance matching based on the control signal transmitted from the controller 160.

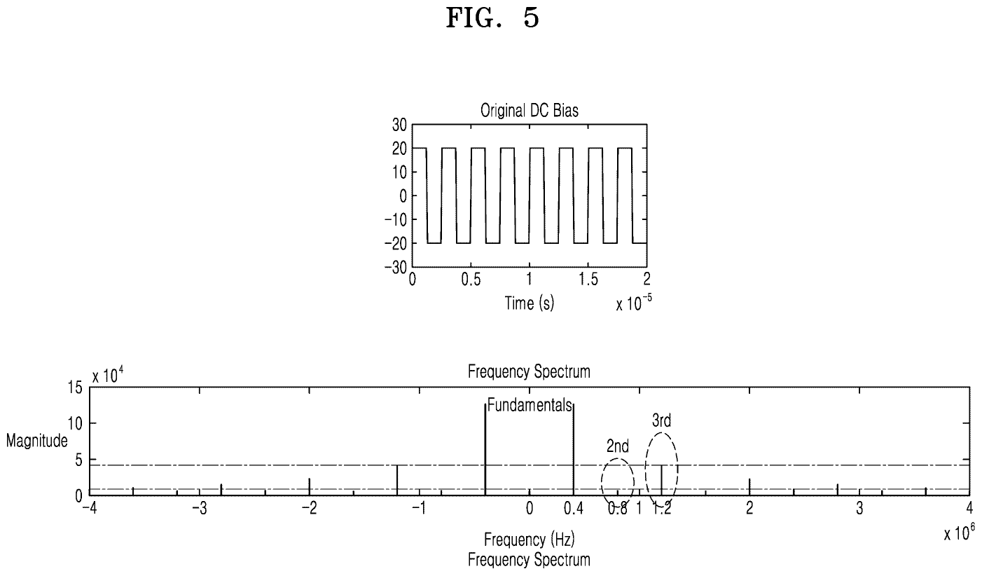

Each of the compensation circuits in FIG. 3, although not shown in the drawing, may be connected to at least one of a matcher and an impedance controller, and may be configured to control impedance of a frequency of the compensation signal as the harmonic signal generated by the second function output unit 110b as well as a frequency of the first harmonic signal generated by the first function output unit 110a. In detail, frequencies of even and odd multiples of the frequency of the first harmonic signal generated from the first function output unit 110a may be controlled, and control of the even and odd multiple frequencies will be described in detail with reference to FIGS. 5 to 9.

FIG. 4 is a conceptual diagram listing a modified example of a compensation signal.

Referring to FIG. 4 together with FIGS. 1 to 3, FIG. 4A is a diagram showing a waveform of the first harmonic signal generated from the first function output unit 110a. The frequency of the first harmonic signal generated from the first function output unit 110a is defined as a fundamental frequency. FIGS. 4B to 4E are diagrams showing a waveform of the compensation signal generated by the second function output unit 110b. A frequency of the compensation signal shown in FIG. 4 is shown to be the same as the fundamental frequency, but embodiments are not limited thereto, and the fundamental frequency and the frequency of the compensation signal may be different from each other. The different frequency of the compensation signal may be formed by the control unit 114 included in the second function output unit 110b.

FIG. 4B is a diagram showing a waveform of a compensation signal having a different amplitude compared to the first harmonic signal generated from the first function output unit 110a.

FIG. 4C is a diagram showing a waveform of a compensation signal having a different shape from the first harmonic signal generated from the first function output unit 110a. In the drawing, a compensation signal forming a waveform similar to a parallelogram is shown according to an embodiment, but a modified shape is not limited thereto.

FIG. 4D is a diagram showing a waveform of a compensation signal having a different slope from the first harmonic signal generated from the first function output unit 110a.

FIG. 4E is a diagram showing a waveform of a compensation signal having a different phase compared to the first harmonic signal generated from the first function output unit 110a. In more detail, FIG. 4E illustrates the case in which a different phase from the first harmonic signal generated from the first function output unit 110a is formed based on a modified shape of FIG. 4C. That is, the compensation signal may have a falling phase at a length or time of a rising phase of the first harmonic signal generated from the first function output unit 110a, and thus it may be seen that the first harmonic signal and the compensation signal have the phases that are opposite to each other. When the phases are formed differently, if the first harmonic signal and the compensation signal generated from the first function output unit 110a overlap each other, the signals may cancel each other in the opposite phase section alone. When the phases of the signals generated from the first function output unit 110a and the second function output unit 110b are the same, if the signals overlap each other, the signals reinforce each other in the same phase section alone.

FIGS. 5 to 9 are graphs showing a process of compensating for a deteriorated first harmonic signal.

In the compensation process, in FIGS. 5 to 9, the fundamental frequency, which is a frequency of the first harmonic signal output from the first function output unit 110a, is set to about 400 kHz according to an embodiment, but the frequency is not limited thereto. Hereinafter, repeated descriptions will be omitted.

Referring to FIG. 5 together with FIGS. 1 to 4, a graph showing the first harmonic signal generated from the first function output unit 110a over time is shown in an upper side, and the magnitude of a signal with respect to a frequency is shown in a lower side. Hereinafter, the meaning of the graphs is the same as in FIGS. 5 to 9, and thus repeated descriptions are omitted.

With reference to the graph showing the first harmonic signal over time, which is shown in the upper side, the first harmonic signal generated from the first function output unit 110a may be in the form of a square wave. The intensity of the signal may be constant in a certain time range, and in the case of the certain time, the intensity of the signal may decrease or increase vertically.

With reference to the magnitude of the first harmonic signal with respect to a frequency, which is shown in the lower side, 800 kHz, which is twice an even multiple of a fundamental frequency of 400 kHz may be shown to be the 2^{nd}, and 1.2 MHz, which is three times an odd multiple of the fundamental frequency of 400 kHz, may be shown as the 3^{rd}. When the first harmonic signal proceeds in a different direction, the frequency may be negative, and even in the case of negative numbers, the absolute values of the first harmonic signal are the same. In FIG. 5, the magnitude of the 2^{nd} signal, which is the first signal of the even-numbered wave, and the magnitude of the 3^{rd} signal, which is the first signal of the odd-numbered wave, are indicated by dashed-dotted lines on the graph, and the magnitude of the indicated dashed-dotted lines is the size of the first harmonic signal that is not deteriorated and is defined as a reference value. Hereinafter, in the graphs, the dashed-dotted lines are indicated in the same manner, and thus a description thereof is omitted.

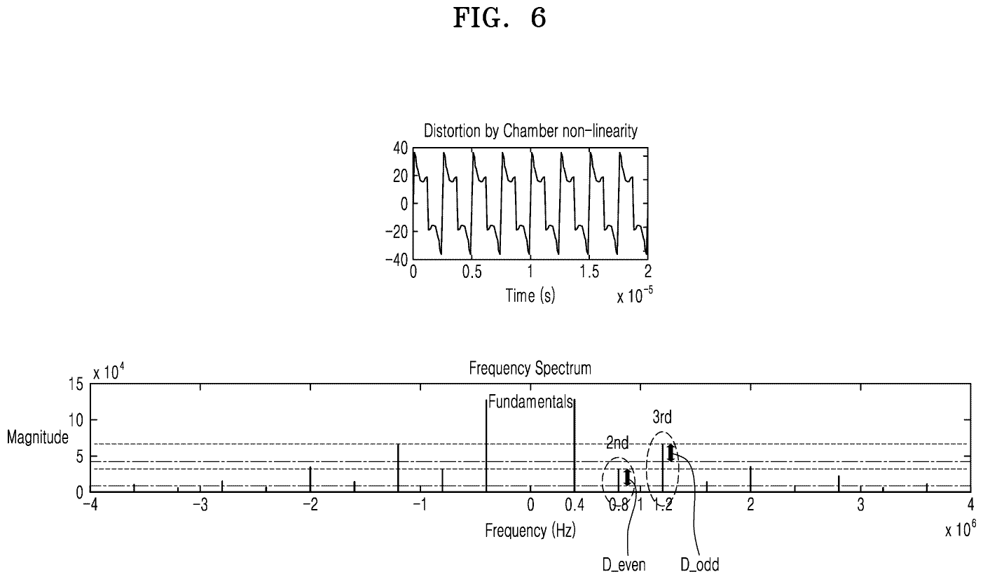

Referring to FIG. 6 together with FIGS. 1 to 5, a graph showing a shape of a signal deteriorated by a circuit component located on a path, through which the first harmonic signal generated by the first function output unit 110a proceeds to the substrate processing device 1000 over time is shown in an upper side, and the magnitude of a signal with respect to a frequency for the deteriorated signal is shown in a lower side.

With reference to the graph showing the first harmonic signal over time, which is shown in the upper side, the first harmonic signal generated from the first function output unit 110a is not in the form of a square wave, and the intensity of the signal is not constant over a certain time range. As described above, this means that the signal is deteriorated and distorted by a plurality of circuit components located on the path.

With reference to the magnitude of the first harmonic signal with respect to a frequency, which is shown in the lower side, based on a dashed-dotted line as the reference value shown in FIG. 5, distortion may occur in the magnitudes of a signal of 800 kHz of an even multiple of the reference value and a signal of 1.2 MHz of an odd multiple of the reference value. In more detail, even harmonics distortion D_even equal to a size of an arrow compared to a dashed-dotted line occurs in the magnitude of the 2^{nd} frequency of 800 kHz, and odd harmonics distortion D_odd equal to a size of an arrow compared to the dashed-dotted line occurs in the magnitude of the 3^{rd} frequency. The magnitudes of the even harmonics distortion D_even and the odd harmonics distortion D_odd are not limited to the drawings.

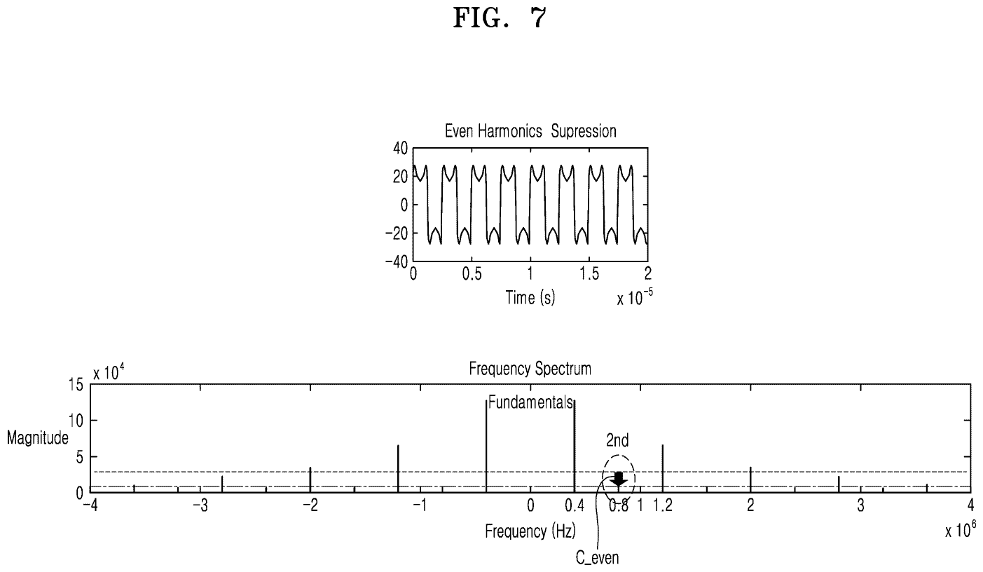

Referring to FIG. 7 together with FIGS. 1 to 6, a graph showing compensation for the even harmonics distortion D_even of FIG. 6 is shown.

With reference to the graph showing the first harmonic signal over time, which is shown in the upper side, a shape of the first harmonic signal with compensation for the even multiple frequency for the deteriorated first harmonic signal of FIG. 6 is shown. Distorted and deteriorated harmonics may be compensated for by changing the impedance of the control signal of the controller 160 by the plurality of compensation circuits 124 of the filter 120 and generating the compensation signal by the second function output unit 110b of the power generator 110. When the frequency of the first harmonic signal generated from the first function output unit 110a is defined as the fundamental frequency, the frequency of the compensation signal generated from the second function output unit 110b may be an even multiple of the fundamental frequency. Each of the plurality of compensation circuits 124 may be configured to match impedances corresponding to respective frequencies of the first harmonic signal and the compensation signal that are generated by the first function output unit 110a and the second function output unit 110b, respectively. Therefore, the deteriorated portion of the first harmonic signal may be compensated for by the second function output unit 110b and the compensation circuit 124, and in this case, compensation includes not only cancellation but also reinforcement of the first harmonic signal.

With reference to the magnitude of the first harmonic signal with respect to a frequency, which is shown in the lower side, even harmonics compensation C_even may be performed on the magnitude of the 2^{nd} signal, which is 800 kHz as an even multiple, while a value of even harmonics distortion D_even decreases from a dotted line to a dashed-dotted line as a reference value. When the even harmonics compensation C_even is performed by the second function output unit 110b and the compensation circuit 124, the magnitude of the even multiple may be returned to a dashed-dotted line as the reference value.

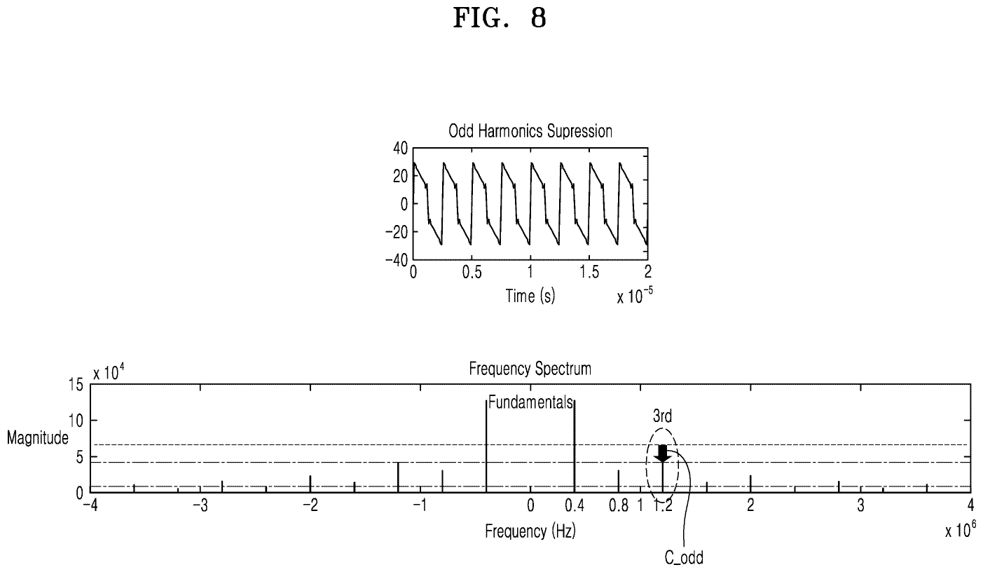

Referring to FIG. 8 together with FIGS. 1 to 6, a graph showing compensation for the odd harmonics distortion D_odd of FIG. 7 is shown.

With reference to the graph showing the first harmonic signal over time, which is shown in the upper side, a shape of the first harmonic signal with compensation for the odd multiple frequency for the deteriorated first harmonic signal of FIG. 6 is shown. Distorted and deteriorated harmonics may be compensated for by changing the impedance of the control signal of the controller 160 by the plurality of compensation circuits 124 of the filter 120 and generating the compensation signal by the second function output unit 110b of the power generator 110. When the frequency of the first harmonic signal generated from the first function output unit 110a is defined as the fundamental frequency, the frequency of the compensation signal generated from the second function output unit 110b may be an odd multiple of the fundamental frequency. Each of the plurality of compensation circuits 124 may be configured to match impedances corresponding to frequencies of the first harmonic signal and the compensation signal that are generated by the first function output unit 110a and the second function output unit 110b, respectively. Therefore, the deteriorated portion of the first harmonic signal may be compensated for by the second function output unit 110b and the compensation circuit 124, and in this case, compensation includes not only cancellation but also reinforcement of the first harmonic signal.

With reference to the magnitude of the first harmonic signal with respect to a frequency, which is shown in the lower side, odd harmonics compensation C_odd may be performed on the magnitude of the 3^{rd} signal, which is 1.2 kHz as an odd multiple, while a value of odd harmonics distortion D_odd decreases from a dotted line to a dashed-dotted line as a reference value. When the odd harmonics compensation C_odd is performed by the second function output unit 110b and the compensation circuit 124, the magnitude of the odd multiple may be returned to a dashed-dotted line as the reference value.

With regard to the even harmonics compensation C_even and the odd harmonics compensation C_odd shown in FIGS. 7 and 8, the even harmonics compensation C_even is performed and then the odd harmonics compensation C_odd is sequentially performed, but sequences of the even harmonics compensation C_even and the odd harmonics compensation C_odd may be interchanged and the even harmonics compensation C_even and the odd harmonics compensation C_odd may be performed simultaneously.

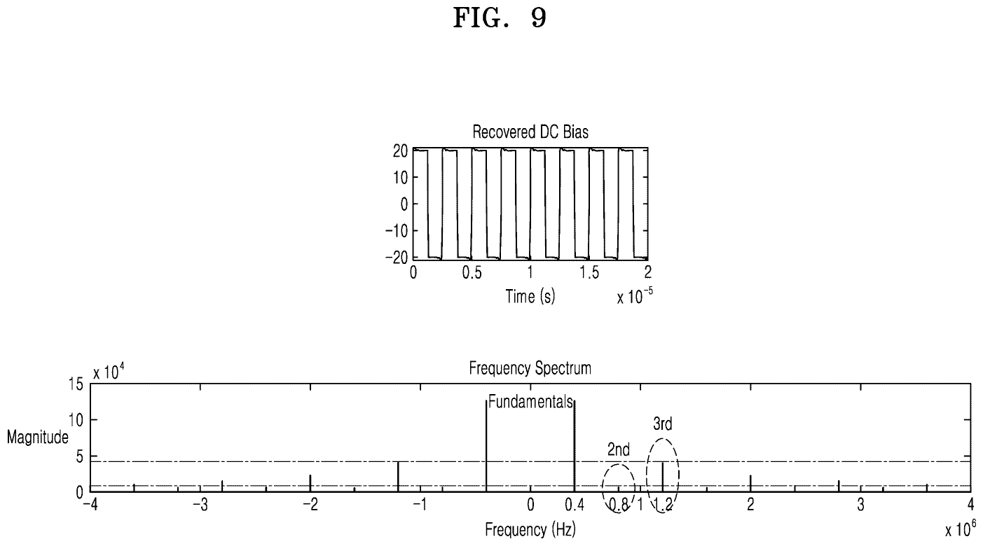

Referring to FIG. 9 together with FIGS. 1 to 8, the deteriorated first harmonic signal of FIG. 6 is recovered through the even harmonics compensation C_even and the odd harmonics compensation C_odd of FIGS. 7 and 8.

With reference to the graph showing the first harmonic signal over time, which is shown in the upper side, the present first harmonic signal does not have the exact same waveform as an initial first harmonic signal of FIG. 5, but the present first harmonic signal is in the form of a square wave in which the intensity of the signal is constant in a certain time range and the intensity of the signal decreases or increases vertically in a certain time range.

As seen from the magnitude of the first harmonic signal with respect to a frequency, which is shown in the lower side, the magnitudes of both the 2^{nd} signal, which is 800 kHz as an even multiple of a fundamental frequency of 400 kHz, and the 3^{rd} signal, which is 1.2 MHz as an odd multiple of the fundamental frequency of 400 kHz, are recovered to a dashed-dotted line as a reference value.

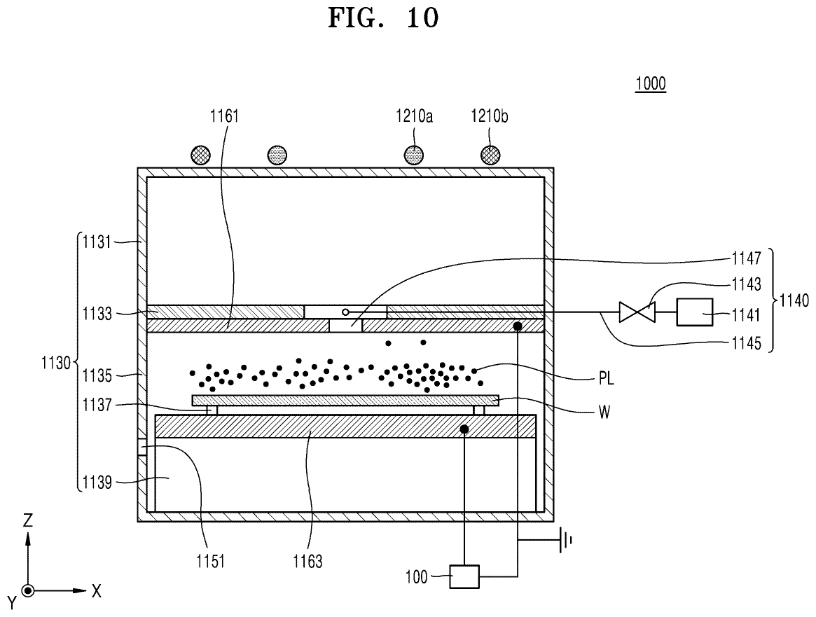

FIG. 10 is a diagram for explaining a substrate processing device including a plasma generation circuit according to an embodiment.

Referring to FIG. 10 together with FIGS. 1 to 9, the substrate processing device 1000 may include a chamber 1130 constituting a space for plasma-processing a substrate W, a gas supply 1140 supplying plasma gas into the chamber 1130, and the plasma generation circuit 100 that induces a plasma generation reaction of the plasma gas. The present plasma generation circuit 100 may correspond to the plasma generation circuit 100 shown in FIG. 1.

The substrate processing device 1000 may process the substrate W within a process chamber using plasma. For example, the substrate processing device 1000 may be a plasma etching device performing a plasma etching process. The substrate processing device 1000 may be configured to perform a semiconductor device manufacturing process. The substrate processing device 1000 may include a capacitively coupled plasma source, an inductively coupled plasma source, a microwave plasma source, and a remote plasma source. The substrate processing device 1000 according to an embodiment may perform plasma processing using an inductively coupled plasma source. The substrate processing device 1000 may also perform substrate processing processes such as plasma annealing, etching, plasma enhanced chemical vapor deposition, plasma enhanced atomic layer deposition, physical vapor deposition, and plasma cleaning.

The substrate processing device 1000 may perform, for example, a reactive ion etching process. The reactive ion etching is a dry etching process in which excited species (radicals or ions) excited by a high-frequency RF power source etch a substrate or a thin film in a low-pressure chamber. The reactive ion etching may be performed by bombardment of energetic ions and the complexity of physical and chemical actions of chemically active species. The reactive ion etching may include etching of insulating layers such as silicon oxide, etching of metallic materials, and etching of doped or undoped semiconductor materials. The substrate processing device 1000 may be a device for processing the substrate W by using generated plasma.

The substrate W may be a wafer, for example, a silicon wafer. The substrate W may include a semiconductor element such as germanium (Ge), or a compound semiconductor such as silicon carbide (SiC), gallium arsenide (GaAs), indium arsenide (InAs), and indium phosphide (InP). The substrate W may have a silicon on insulator (SOI) structure. The substrate W may include a buried oxide layer. The substrate W may include a conductive region, for example, a well doped with impurities. The substrate W may have various device isolation structures such as shallow trench isolation (STI) that separates the doped walls from each other. The substrate W may have a first surface that is an active surface and a second surface that is an inactive surface opposite to the first surface. The second surface of the substrate W may face a chuck 1137 to be described below. A material film, for example, an oxide film or a nitride film, may be formed on the substrate W.

The chamber 1130 may include an upper housing 1131, a lower housing 1135 located below the upper housing 1131, a window 1133 located between the upper housing 1131 and the lower housing 1135, and a chuck 1137 supporting the substrate W. A chuck support 1139 may be located below the chuck 1137.

The chamber 1130 may be, for example, the plasma chamber 1130. The chamber 1130 may include metal such as aluminum (Al). The chamber 1130 has an approximately cylindrical shape. The chamber 1130 may provide a processing space for processing the substrate W. The processing space may include the upper housing 1131 and the lower housing 1135. The chamber 1130 may isolate the processing space from the outside, and thus process parameters such as pressure, temperature, partial pressure of the processing gas, and plasma density may be precisely controlled. (An internal space of) the chamber 1130 may have cylindrical symmetry.

According to embodiments, the chamber 1130 may provide a plasma region. The plasma region refers to all spaces affected by plasma, such as a space in which plasma is formed and a sheath region, during processing of the substrate W. The plasma region may be simply viewed as the space between the chuck 1137 and the window 1133.

A center antenna 1210a and an edge antenna 1210b that are apart from the chuck 1137 upward may be provided in the upper housing 1131. The center antenna 1210a and the edge antenna 1210b may be fixed to an upper portion of the window 1133. The center antenna 1210a and the edge antenna 1210b may face the chuck 1137. The center antenna 1210a and the edge antenna 1210b may be connected to a high frequency power source. The high frequency power source may generate RF power and supply the generated RF power to the center antenna 1210a and the edge antenna 1210b through an impedance matcher.

The gas supply 1140 may include a gas source 1141 that supplies gas inside the chamber 1130, a gas valve 1143 connected to the gas source 1141 and controlling the amount of the supplied gas, a gas supply line 1145 that provides a path through which the gas moves, and a gas supply nozzle 1147 that supplies gas between the window 1133 and the substrate W.

The gas supply nozzle 1147 may uniformly disperse the process gas introduced into the chamber 1130. The gas supply nozzle 1147 may be located in an internal space of the chamber 1130. The gas supply nozzle 1147 may face the chuck 1137. The gas supply nozzle 1147 may have an annular sidewall and a disk-shaped injection plate. A plurality of injection holes are formed in the entire area of the injection plate. The process gas supplied through the gas source 1141 may be injected into the internal space of the chamber 1130 through the injection hole of the gas supply nozzle 1147. The chamber 1130 may further include an exhaust device for exhausting reactants, debris, processing gas, and plasma after processing the substrate W. According to an embodiment, the exhaust device may be an exhaust hole 1151.

The chuck 1137 may be provided on the chuck support 1139 and may support the substrate W above the chuck 1137. The chuck 1137 may be an electrostatic chuck (ESC) configured to fix the substrate W by electro-static force. The chuck 1137 may fix the substrate W by using electro-static force. The chuck 1137 may be provided in a process chamber configured to perform a semiconductor manufacturing process using plasma, for example, etching, deposition, and cleaning.

Upper electrodes 1161 may be located at both ends of the gas supply nozzle 1147, and a lower electrode 1163 may face the upper electrodes 1161 and located below the substrate W. The plasma generation circuit 100 may be connected to each of the upper electrode 1161 and the lower electrode 1163. The plasma generation circuit 100 may correspond to the plasma generation circuit 100 described with reference to FIG. 1.

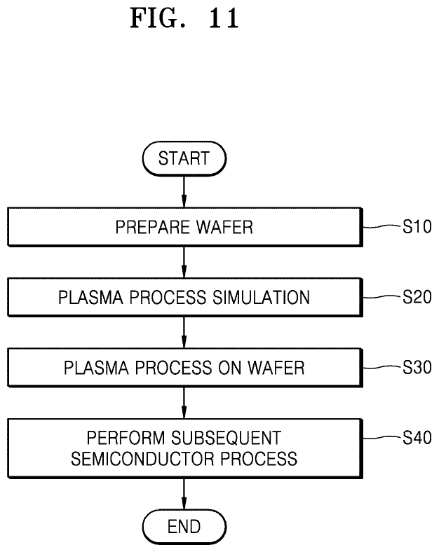

FIG. 11 is a flowchart of a semiconductor device manufacturing method including plasma process simulation according to an embodiment.

Referring to FIG. 11, the substrate W may be prepared inside the chamber 1130 (S10). For example, the substrate W may be located on the chuck 1137 of the chamber 1130. The chuck 1137 may be a stage that supports the substrate W. For example, the chuck 1137 may be an ESC.

Then, plasma process simulation for the substrate W may be performed (S20). For example, the plasma process may include any plasma processes such as a plasma etching process, a plasma annealing process, and/or a plasma cleaning process.

The plasma process simulation in operation S20 may include defining a plasma reaction, calculating a reaction parameter, generating a plasma process simulation profile, and generating a final simulation profile.

Then, based on the plasma process simulation, plasma processing on the substrate W may be performed (S30). Plasma processing may include etching, deposition, and cleaning processes for the substrate W using plasma.

After plasma processing the substrate W, a subsequent semiconductor process is performed on the substrate W (S40). The subsequent semiconductor process for the substrate W may include various processes. For example, the subsequent semiconductor process may include a deposition process, an etching process, an ion process, and a cleaning process. These subsequent semiconductor process may or may not use plasma. The subsequent semiconductor process may include a singulation process for individualizing the substrate W into each semiconductor chip, a test process for testing the semiconductor chips, and a packaging process for packaging the semiconductor chips. A semiconductor device may be completed through the subsequent semiconductor process on the substrate W.

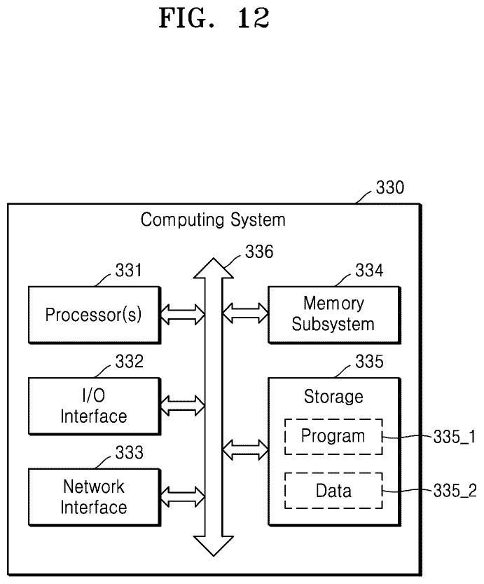

FIG. 12 is a block diagram showing a computing system according to an embodiment. In some embodiments, a plasma process simulation method S20 may be performed in a computing system 330 of FIG. 12.

Referring to FIG. 12, the computing system 330 may be a stationary computing system such as a desktop computer, a workstation, or a server, or a portable computing system such as a laptop computer. As shown in FIG. 9, the computing system 330 may include at least one processor 331, an input/output interface 332, a network interface 333, a memory subsystem 334, and a storage 335, and the at least one processor 331, the input/output interface 332, the network interface 333, the memory subsystem 334, and the storage 335 may communicate with each other through a bus 336.

The at least one processor 331 may be referred to as a processing unit and may execute any instruction set (e.g., Intel architecture-32 (IA-32), 64-bit extension IA-32, ×86-64, PowerPC, Sparc, MIPS, ARM, or IA-64), like in a micro-processor, an application processor (AP), a digital signal processor (DSP), or a graphic processing unit (GPU). For example, the at least one processor 331 may access the memory subsystem 334 through the bus 336 and execute instructions stored in the memory subsystem 334.

The input/output interface 332 may include an input device such as a keyboard or a pointing device, and/or an output device such as a display device or a printer or may provide access to an input device and/or an output device. Through the input/output interface 332, a user may trigger execution of a program 335_1 and/or loading of data 335_2, input ion information, material information, and/or neutral radical information, and check output data.

The network interface 333 may provide access to a network outside the computing system 330. For example, a network may include multiple computing systems and communication links, which may include wired links, optical links, wireless links, or any other type of links.

The memory subsystem 334 may store the program 335_1 or at least a portion thereof for a method of modeling damage caused by incident particles as described above with reference to the drawings, and the at least one processor 331 may perform at least some of operations included in the method of modeling damage caused by incident particles by executing the programs (or instructions) stored in the memory subsystem 334. The memory subsystem 334 may include read only memory (ROM) and random access memory (RAM).

The storage 335 may be a non-transitory storage medium, and stored data may not be lost even if power supplied to the computing system 330 is shut off. For example, the storage 335 may include a non-volatile memory device, or may include a storage medium such as magnetic tape, optical disk, or magnetic disk. The storage 335 may be removable from the computing system 330. As shown in FIG. 11, the program 335_1 and the data 335_2 may be stored. Before being executed by the at least one processor 331, at least a portion of the program 335_1 may be loaded into the memory subsystem 334. In some embodiments, the storage 335 may store a file written in a program language, and the program 335_1 generated by a compiler or the like from the file or at least a portion thereof may be loaded into the memory subsystem 334. The data 335_2 may include data necessary to perform the plasma process simulation method described above with reference to the drawings, such as ion information, material information, and/or neutral radical information. The data 335_2 may include output data generated by performing the plasma process simulation method described above with reference to the drawings.

The embodiments described above are merely illustrative, and various modifications and other equivalent embodiments may be made by those skilled in the art. Therefore, the true scope according to the embodiments needs to be determined by the technical spirit described in the following claims.

Various changes in form and details may be made in embodiments without departing from the spirit and scope of the following claims.

What is claimed is:

1. A plasma generation circuit comprising:
a power generator comprising a first function output unit configured to generate a first harmonic signal and a second function output unit configured to generate a compensation signal;
a load unit electrically connected to one side of the power generator and configured to transmit the first harmonic signal and the compensation signal to a sensor; and
a controller connected to the power generator and the sensor,
wherein the sensor is provided between the load unit and an electrode configured to generate plasma based on receiving the first harmonic signal and the compensation signal,
wherein the controller is configured to generate a control signal based on the first harmonic signal received from the sensor, and
wherein the second function output unit is configured to generate the compensation signal based on the control signal.

2. The plasma generation circuit of claim 1, wherein the second function output unit comprises:
a control signal analyzer configured to analyze the control signal received from the controller;
a pulse synchronizer configured to generate the compensation signal having a same frequency as the first harmonic signal generated by the first function output unit; and
a clock pulse generator configured to generate the compensation signal.

3. The plasma generation circuit of claim 1, wherein the second function output unit comprises a control unit configured to control each of a phase, a frequency, and an amplitude of the compensation signal.

4. The plasma generation circuit of claim 1, wherein the second function output unit comprises:
a digital to analog converter (DAC); and
an amplifier.

5. The plasma generation circuit of claim 1, wherein the compensation signal is different from the first harmonic signal in at least one of an amplitude, a shape, a slope, and a phase.

6. The plasma generation circuit of claim 1, wherein a first frequency of the first harmonic signal generated by the first function output unit is a fundamental frequency, and a second frequency of the compensation signal generated by the second function output unit is an even multiple of the fundamental frequency.

7. The plasma generation circuit of claim 1, wherein a first frequency of the first harmonic signal generated by the first function output unit is a fundamental frequency, and a second frequency of the compensation signal generated by the second function output unit is an odd multiple of the fundamental frequency.

8. The plasma generation circuit of claim 1, wherein the first harmonic signal generated by the first function output unit is compensated for by the compensation signal generated by the second function output unit at the electrode.

9. The plasma generation circuit of claim 1, further comprising a filter configured to adjust the first harmonic signal and the compensation signal,
wherein the filter comprises a plurality of compensation circuits.

10. The plasma generation circuit of claim 9, wherein each of the plurality of compensation circuits is configured to match impedances at respective frequencies of the first harmonic signal generated by the first function output unit and the compensation signal generated by the second function output unit, and
wherein the impedances are adjusted by the controller.

11. A plasma generation circuit for supplying power to a plasma chamber, the plasma generation circuit comprising:
a power generator comprising a first function output unit configured to generate a first harmonic signal transmitted to the plasma chamber and a second function output unit configured to generate a compensation signal;
a filter electrically connected to the power generator and configured to adjust the first harmonic signal and the compensation signal;
a sensor provided on an electrode of the plasma chamber and configured to measure a voltage and a current of each of the first harmonic signal and the compensation signal;
a load unit located between the power generator and the sensor and configured to transmit the first harmonic signal and the compensation signal generated by the power generator to the sensor; and
a controller connected to the power generator, the filter, and the sensor,
wherein the controller is configured to generate a control signal based on the first harmonic signal received from the sensor,
wherein the control signal is transmitted to the power generator and the filter,
wherein the compensation signal is generated based on the control signal generated by the second function output unit,
wherein the filter comprises a plurality of compensation circuits, and
wherein impedances of the plurality of compensation circuits are adjusted by the control signal generated by the controller.

12. The plasma generation circuit of claim 11, wherein the electrode comprises an upper electrode and a lower electrode, and
at least one compensation circuit of the plurality of compensation circuits is connected to the upper electrode.

13. The plasma generation circuit of claim 11, wherein a first compensation circuit among the plurality of compensation circuits comprises a compensation capacitor, a compensation variable capacitor, and a compensation inductor.

14. The plasma generation circuit of claim 13, wherein the compensation inductor is connected in series to one of the compensation capacitor and the compensation variable capacitor.

15. The plasma generation circuit of claim 13, wherein the compensation inductor is connected in parallel to one of the compensation capacitor and the compensation variable capacitor.

16. The plasma generation circuit of claim 11, wherein an impedance of each of the plurality of compensation circuits is matched with a frequency of each of the first harmonic signal and the compensation signal.

17. The plasma generation circuit of claim 11, wherein the second function output unit comprises:
a control signal analyzer configured to analyze the control signal received from the controller;
a pulse synchronizer configured to generate the compensation signal having a frequency that is the same as a frequency as the first harmonic signal;
a clock pulse generator configured to generate the compensation signal; and
a control unit configured to control a phase, the frequency, and an amplitude of the compensation signal.

18. The plasma generation circuit of claim 11, wherein the compensation signal is different from the first harmonic signal in at least one of an amplitude, a shape, a slope, and a phase.

19. A plasma generation circuit mounted in a chamber including an electrode unit comprising an upper electrode and a lower electrode that are configured to cause a plasma generation reaction from the plasma gas, configured to transmit a first harmonic signal to the upper electrode and the lower electrode,
the plasma generation circuit comprising:
a power generator comprising a first function output unit configured to generate the first harmonic signal and a second function output unit configured to generate a compensation signal;
a filter electrically connected to the power generator and configured to adjust the first harmonic signal and the compensation signal;
a sensor located on the upper electrode or the lower electrode and configured to measure a voltage and a current of each of the first harmonic signal and the compensation signal;
a load unit located between the power generator and the sensor and configured to transmit the first harmonic signal and the compensation signal generated by the power generator to the sensor; and
a controller connected to the power generator, the filter, and the sensor, and configured to generate a control signal based on the first harmonic signal received from the sensor,
wherein the second function output unit is configured to generate the compensation signal as a second harmonic signal based on the control signal,
wherein the filter comprises a plurality of compensation circuits,
wherein at least one compensation circuit of the plurality of compensation circuits is connected to the upper electrode, and
wherein impedances of the plurality of compensation circuits are adjusted by the control signal generated by the controller.

20. The plasma generation circuit of claim 19, wherein a first frequency of the first harmonic signal is as a fundamental frequency,
wherein a second frequency of the compensation signal is an even multiple or an odd multiple of the fundamental frequency,
wherein the first harmonic signal is compensated for by the compensation signal generated by the second function output unit at an electrode, and
wherein each of the plurality of compensation circuits is configured to match the impedances of the plurality of compensation circuits at respective frequencies of the first harmonic signal and the compensation signal.
